(19) United States
(12) Patent Application Publication
(10) Pub. No.: US 2026/0255477 A1
(43) Pub. Date: Aug. 27, 2026

(54) PRINTED CIRCUIT BOARD

(71) Applicant: SAMSUNG ELECTRO-MECHANICS CO., LTD., Suwon-si (KR)

(72) Inventors: Kwang Su KIM, Suwon-si (KR); Joung Hun KIM, Suwon-si (KR); Sang Kee YOON, Suwon-si (KR); Tae Kyung LEE, Suwon-si (KR); Jin Uk LEE, Suwon-si (KR)

(73) Assignee: SAMSUNG ELECTRO-MECHANICS CO., LTD., Suwon-si (KR)

(21) Appl. No.: 19/442,136

(22) Filed: Jan. 7, 2026

(30) Foreign Application Priority Data
Feb. 24, 2025 (KR) 10-2025-0023889

(51) Int. Cl. H05K 1/02; H05K 1/03; H05K 1/11

(52) U.S. Cl. CPC H05K 1/0298; H05K 1/036; H05K 1/115

(57) ABSTRACT

A printed circuit board includes a first insulating layer, a first wiring layer disposed on the first insulating layer, and a first insulating film disposed on the first insulating layer, the first insulating film covering at least a portion of each of an upper surface and a side surface of the first wiring layer conforming to a shape of the first wiring layer. The first insulating layer has a first recess portion around the first wiring layer. A depth of the first recess portion is greater than 0 μm and less than 1.0 μm.

### CROSS-REFERENCE TO RELATED APPLICATION(S)

This application claims benefit of priority to Korean Patent Application No. 10-2025-0023889 filed on February 24, 2025 in the Korean Intellectual Property Office, the disclosure of which is incorporated herein by reference in its entirety.

### TECHNICAL FIELD

The present disclosure relates to a printed circuit board.

Recently, a technology for arranging multiple semiconductor chips on a Si interposer and connecting the semiconductor chips through high-density interconnect techniques has been actively developed. However, in the case of a Si interposer, a semiconductor technology such as a through-silicon via (TSV) may be generally applied thereto, which may result in high process costs. To address such an issue, embedding a Si bridge within a package substrate has been proposed to reduce a process ratio. Nevertheless, even in this case, it may be applicable only to high-cost electronic devices in terms of cost. Accordingly, a new packaging technology capable of reducing costs while enabling high-density interconnects between chips has been required.

### SUMMARY

An aspect of the present disclosure is to provide a printed circuit board capable of reducing costs and implementing a fine wiring substrate having excellent reliability.

According to an aspect of the present disclosure, there is provided a printed circuit board including a first insulating layer, a first wiring layer disposed on the first insulating layer, and a first insulating film disposed on the first insulating layer, the first insulating film covering at least a portion of each of an upper surface and a side surface of the first wiring layer conforming to a shape of the first wiring layer. The first insulating layer may have a first recess portion around the first wiring layer. A depth of the first recess portion may be greater than 0 μm and less than 1.0 μm.

According to another aspect of the present disclosure, there is provided a printed circuit board including a first insulating layer, a plurality of wirings disposed on the first insulating layer, and an insulating film disposed on the first insulating layer, the insulating film covering each of the plurality of wirings conforming to a shape of each of the plurality of wirings. Each of the plurality of wirings may include a first metal portion and a second metal portion disposed on the first metal portion, the second metal portion being thicker than the first metal portion. The first metal portion may have a width greater than that of the second metal portion in cross-section. The first insulating layer may have a recess portion between the first metal portions of at least two adjacent wirings, among the plurality of wirings.

According to example embodiments of the present disclosure, a printed circuit board may reduce costs and implement a fine wiring substrate having excellent reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board;

FIGS. 3 and 4 are schematic process cross-sectional views of a manufacturing example of the printed circuit board of FIG. 2;

FIG. 5 is a schematic cross-sectional view of another example of a printed circuit board;

FIG. 6 is a schematic cross-sectional image of an implementation example of region “A” of the printed circuit board of FIG. 5;

FIG. 7 is a schematic cross-sectional image of an implementation example of region “B” of the printed circuit board of FIG. 5;

FIG. 8 is a schematic cross-sectional view of an example of a semiconductor package; and

FIG. 9 is a schematic cross-sectional view of another example of a semiconductor package.

### DETAILED DESCRIPTION

Hereinafter, the present disclosure will be described with reference to the accompanying drawings. In the drawings, the shapes, sizes, and the like of components may be exaggerated or reduced for clarity of description.

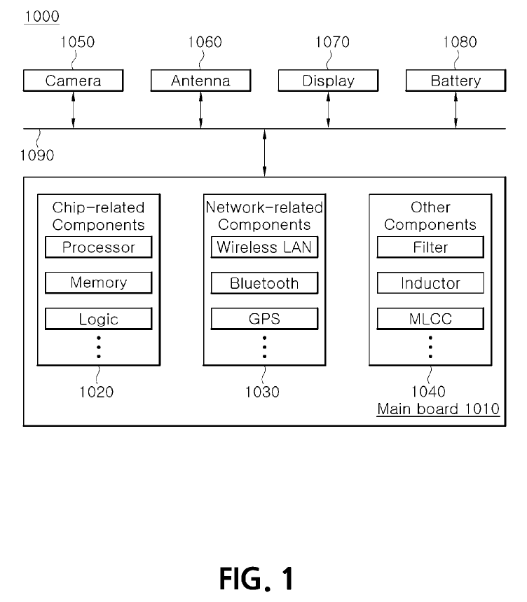

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

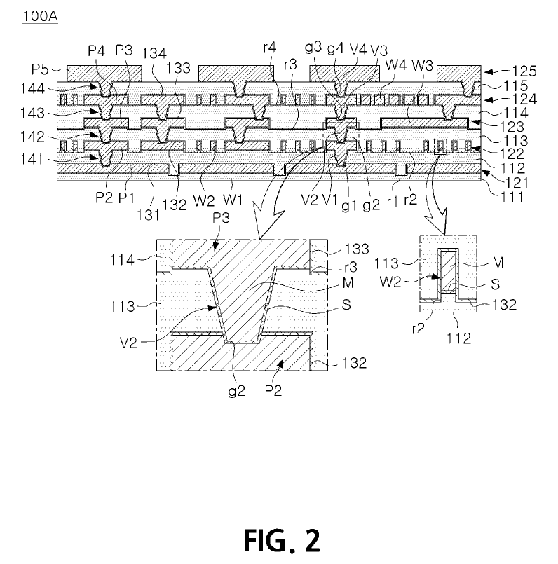

FIG. 2 is a schematic perspective view of an example of an electronic device.

Referring to the drawings, a printed circuit board 100A according to an example may include a plurality of insulating layers 111, 112, 113, 114, and 115, a plurality of wiring layers 121, 122, 123, and 124 respectively disposed in the plurality of insulating layers 111, 112, 113, 114, and 115, a plurality of insulating films 131, 132, 133, and 134 respectively disposed between the plurality of insulating layers 111, 112, 113, 114, and 115, the plurality of insulating films 131, 132, 133, and 134 respectively covering at least portions of the plurality of wiring layers 121, 122, 123, and 124 conforming to shapes of the plurality of wiring layers 121, 122, 123, and 124, and a plurality of via layers 141, 142, and 143 respectively disposed in the plurality of insulating layers 111, 112, 113, 114, and 115, the plurality of via layers 141, 142, and 143 connecting the plurality of wiring layers 121, 122, 123, and 124 to each other. For example, the printed circuit board 100A may have a coreless multilayer substrate structure, but the present disclosure is not limited thereto. The printed circuit board 100A according to an example may have a low-layer substrate structure including only one insulating layer and one wiring layer or two insulating layers and/or two wiring layers, as necessary. In addition, a core layer and/or a build-up layer may further be disposed on lower sides of the plurality of insulating layers 111, 112, 113, 114, and 115, as necessary.

Each of the plurality of insulating layers 111, 112, 113, 114, and 115 may include a photosensitive organic insulating material. For example, each of the plurality of insulating layers 111, 112, 113, 114, and 115 may include one or more of a polyimide-based resin, a phenol-based resin, and a polybenzoxazole-based resin. In this case, a patterning process may be simpler as compared to a silicon interposer or silicon bridge according to the related art, and may be more advantageous in terms of cost. In addition, at least some of the plurality of wiring layers 121, 122, 123, and 124 and the plurality of via layers 141, 142, and 143, formed on the plurality of insulating layers 111, 112, 113, 114, and 115, may be formed with high-density wiring and/or fine pitch. Accordingly, a fine wiring substrate may be provided, and the fine wiring substrate may be easily applied to an interposer. For example, accordingly, the printed circuit board 100A may be applied to manufacturing of an interposer used in various applications, such as a central processing unit (CPU), a graphics processing unit (GPU), and a tensor processing unit (TPU), for high-performance artificial intelligence (AI) and networking, for example, chip on wafer on substrate (CoWoS) and high bandwidth memory (HBM). In addition, the printed circuit board 100A may also be easily applied to an interconnect bridge, and for example, the printed circuit board A may be embedded in a package substrate for die-to-die connection.

Each of the plurality of insulating films 131, 132, 133, and 134 may include an inorganic insulating material. For example, each of the plurality of insulating films 131, 132, 133, and 134 may include one or more of a silicon nitride-based nitride, an aluminum nitride-based nitride, a boron nitride-based nitride, an aluminum oxide-based oxide, and a silicon oxide-based oxide. In this case, an inorganic insulating film may be formed on a surface of the fine wiring substrate, thereby easily preventing moisture permeation even under high-temperature and high-humidity environments such as an unbiased highly accelerated stress test (uHAST) and a biased highly accelerated stress test (bHAST). Accordingly, stable electrical performance may be maintained without migration of fine wirings. Accordingly, the plurality of insulating films 131, 132, 133, and 134 may be easily applied to various models of package fine wiring substrates requiring reliability. The plurality of insulating films 131, 132, 133, and 134 may be formed on both the plurality of insulating layers 111, 112, 113, 114, and 115 and the plurality of wiring layers 121, 122, 123, and 124, but the present disclosure is not limited thereto. The plurality of insulating films 131, 132, 133, and 134 may be selectively formed only on layers requiring reliability.

The plurality of insulating layers 111, 112, 113, 114, and 115 may have a plurality of recess portions r1, r2, r3, and r4. For example, a first insulating layer 111 may have a first recess portion r1 around a first wiring layer 121, a second insulating layer 112 may have a second recess portion r2around a second wiring layer 122, a third insulating layer 113 may have a third recess portion r3 around a third wiring layer 123, and a fourth insulating layer 114 may have a fourth recess portion r4 around a fourth wiring layer 124. For example, upper surfaces of a region of the first insulating layer 111 in which the first wiring layer 121 is disposed and a region of the first insulating layer 111 in which the first wiring layer 121 is not disposed may have a step portion corresponding to the first recess portion r1, upper surfaces of a region of the second insulating layer 112 in which the second wiring layer 122 is disposed and a region of the second insulating layer 112 in which the second wiring layer 122 is not disposed may have a step portion corresponding to the second recess portion r2, upper surfaces of a region of the third insulating layer 113 in which the third wiring layer 123 is disposed and a region of the third insulating layer 113 in which the third wiring layer 123 is not disposed may have a step portion corresponding to the third recess portion r3, and upper surfaces of a region of the fourth insulating layer 114 in which the fourth wiring layer 124 is disposed and a region of the fourth insulating layer 114 in which the fourth wiring layer 124 is not disposed may have a step portion corresponding to the fourth recess portion r4. Herein, the term “step portion” may refer to an abrupt change in the level of a surface or a difference in the depth, height, or the vertical level of a layer such as an insulating layer. For example, as will be described below, each of the first to fourth wiring layers 121, 122, 123, and 124 may include a seed metal layer formed through a deposition process, for example, a seed metal layer including titanium, which may be selectively removed through dry etching. In this process, portions of the first to fourth insulating layers 111, 112, 113, and 114 may be respectively removed, such that the first to fourth recess portions r1, r2, r3, and r4 may be formed. In this case, a contact area between the plurality of insulating layers 111, 112, 113, 114, and 115 and the plurality of insulating films 131, 132, 133, and 134 may increase, and accordingly, reliability may be further improved. An outermost fifth insulating layer 115 may not have a recess portion, but the present disclosure is not limited thereto. The outermost fifth insulating layer 115 may have a recess portion, as necessary.

The plurality of recess portions r1, r2, r3, and r4may conformally cover the plurality of wiring layers 121, 122, 123 and 124 and the plurality of recess portions r1, r2, r3, and r4 with a substantially constant thickness. For example, the first insulating film 131 may cover at least a portion of each of an upper surface and a side surface of the first wiring layer 121 and at least a portion of each of a lower surface and a side surface of the first recess portion r1 conforming to shapes of the first wiring layer 121 and the first recess portion r1, the second insulating film 132 may cover at least a portion of each of an upper surface and a side surface of the second wiring layer 122, and at least a portion of each of a lower surface and a side surface of the second recess portion r2 conforming to shapes of the second wiring layer 122 and the second recess portion r2, the third insulating film 133 may cover at least a portion of each of an upper surface and a side surface of the third wiring layer 123 and at least a portion of each of a lower surface and a side surface of the third recess portion r3 conforming to shapes of the third wiring layer 123 and the third recess portion r3, and the fourth insulating film 134 may cover at least a portion of each of an upper surface and a lower surface of the fourth wiring layer 124 and at least a portion of each of a lower surface and a side surface of the fourth recess portion r4 conforming to shapes of the fourth wiring layer 124 and the fourth recess portion r4. In this case, a reliability improvement effect may be more easily implemented.

A thickness of each of the plurality of insulating films 131, 132, 133, and 134 may be less than a depth of each of the plurality of recess portions r1, r2, r3, and r4. For example, a thickness of the first insulating film 131 may be less than a depth of the first recess portion r1, a thickness of the second insulating film 132 may be less than a depth of the second recess portion r2, a thickness of the third insulating film 133 may be less than a depth of the third recess portion r3, and a thickness of the fourth insulating film 134 may be less than a depth of the fourth recess portion r4. For example, each of the plurality of recess portions r1, r2, r3, and r4 may have a depth greater than 0 μm and less than 1.0 μm, or greater than 0.01 μm and less than 0.5 μm, and the thickness of each of the plurality of insulating films 131, 132, 133, and 134 may be less than a thickness of each of the plurality of recess portions r1, r2, r3, and r4 within a range greater than 10 Å and less than 10000 Å. As described, the plurality of recess portions r1, r2, r2, and r4 may be formed to have a smaller depth, and the plurality of insulating films 131, 132, 133, and 134 may be formed to have a smaller thickness. In this case, reliability may be improved more effectively while minimizing other side effects such as undulation.

The plurality of wiring layers 121, 122, 123 and 124 may include a plurality of wirings W1, W2, W3, and W4 and/or one or more wirings W1, W2, W3, and W4. For example, the first and third wiring layers 121 and 123 may include a plurality of first and third wirings W1 and W3, and the second and fourth wiring layers 122 and 124 may include one or more second and fourth wirings W2 and W4. In this case, the plurality of first and third wirings W1 and W3 may be relatively fine wirings compared to the one or more second and fourth wirings W2 and W4, respectively. For example, a line width, a spacing, or the like of a wiring may further decrease. For example, the plurality of wiring layers 121, 122, 123 and 124 may have a structure in which the first and third wiring layers 121 and 123 including a high-density wiring and the second and fourth wiring layers 122 and 124 including a low-density wiring are alternately disposed in a lamination direction. In this case, a ground may be disposed on upper and lower portions of a fine wiring, thereby effectively preventing electromagnetic interference.

A plurality of wiring layers 121, 122, 123 and 124 may include a plurality of pads P1, P2, P3, and P4. In addition, the plurality of via layers 141, 142, and 143 may include a plurality of connection vias V1, V2, and V3 connecting the plurality of pads P1, P3, and P4 to each other. For example, a first via layer 141 may include a first connection via V1 connecting a first pad P1 of the first wiring layer 121 and a second pad P2 of the second wiring layer 122 to each other, and a second via layer 142 may include a second connection via V2 connecting the second pad P2 of the second wiring layer 122 and a third pad P3 of the third wiring layer 123 to each other, and a third via layer 143 may include a third connection via V3 connecting the third pad P3 of the third wiring layer 123 and a fourth pad P4 of the fourth wiring layer 124 to each other. In this case, a region of the first pad P1, connected to the first connection via V1, may have a first groove portion g1, a region of the second pad P2, connected to the second connection via V2, may have a second groove portion g2, and a region of the third pad P3, connected to the third connection via V3, may have a third groove portion g3. For example, as will be described below, a via hole for each of the first to third connection vias V1, V2, and V3 may be formed in each of the second to fourth insulating layers 112, 113, and 114, and then the first to third insulating layers P1, P2, and P3 and the other metal oxide films may be removed through dry etching or the like so as to expose the first to third pads P1, P2, and P3. In this process, a portion of each of the first to third pads P1, P2, and P3 may be removed to form the first to third groove portions g1, g2, and g3 in the first to third pads P1, P2, and P3, respectively. The first to third connection vias V1, V2, and V3 may fill the first to third groove portions g1, g2, and g3, respectively, and each of the first to third insulating films 131, 132, and 133 may be in contact with a side surface of each of the first to third connection vias V1, V2, and V3. In this case, a contact area between the first to third connection vias V1, V2, and V3 and the first to third pads P1, P2, and P3 may increase, and thus reliability may be further improved.

As necessary, the printed circuit board 100A according to an example may further include an outermost wiring layer 125 disposed on an uppermost fifth insulating layer 115, among the plurality of insulating layers 111, 112, 113, 114, and 115, and an outermost via layer 144 disposed in the fifth insulating layer 115, the outermost via layer 144 connecting an uppermost fourth wiring layer 124, among the plurality of wiring layers 121, 122, 123, and 124, and the outermost wiring layer 125 to each other. The outermost wiring layer 125 may include an external connection pad P5. The outermost via layer 144 may include a fourth connection via V4 connecting the fourth pad P4 and the external connection pad P5 to each other. In this case, a region of the fourth pad P4, connected to the fourth connection via V4, may have a fourth recess portion g4. For example, as will be described below, a via hole for the fourth connection via V4 may be formed in the fifth insulating layer 115, and then a fourth insulating film 134 and other metal oxide films may be removed through dry etching or the like so as to expose the fourth pad P4. In this process, a portion of the fourth pad P4 may be removed, such that a fourth recess portion g4 may be formed in the fourth pad P4. The fourth connection via V4 may fill the fourth recess portion g4, and the fourth insulating film 134 may be in contact with a side surface of the fourth connection via V4. In this case, a contact area between the fourth connection via V4 and the fourth pad P4 may increase, and thus reliability may be further improved.

The structure illustrated in the drawings may be at least a portion of a substrate structure to which the printed circuit board 100A according to an example embodiment is applied. For example, as described above, the structure illustrated in the drawings may be further expanded vertically by additional formation of a core layer or a build-up layer. The structure illustrated in the drawings may also be further expanded horizontally, such that wirings or patterns embedded in respective insulating layers may not be exposed externally.

Hereinafter, components of the printed circuit board 100A according to an example embodiment will be described in more detail with reference to the drawings.

The plurality of insulating layers 111, 112, 113, 114, and 115 may include an organic insulating material. The organic insulating material may include a photosensitive organic insulating material. For example, the plurality of insulating layers 111, 112, 113, 114, and 115 may each include a polyimide-based resin, a phenol-based resin, and/or a polybenzoxazole-based resin, but the present disclosure is not limited thereto. Other polymer materials capable of simplifying a patterning process may also be used. The plurality of insulating layers 111, 112, 113, 114, and 115 may include substantially the same insulating material, but the present disclosure is not limited thereto. The plurality of insulating layers 111, 112, 113, 114, and 115 may include different insulating materials, as necessary. The number of layers of the plurality of insulating layers 111, 112, 113, 114, and 115 is not limited.

The plurality of wiring layers 121, 122, 123, and 124 and the outermost wiring layer 125 may respectively include a metal. For example, the plurality of wiring layers 121, 122, 123, and 124 and the outermost wiring layer 125 may respectively include a first metal portion and a second metal portion disposed on the first metal portion, the second metal portion being thicker than the first metal portion. The first metal portion may include a seed metal layer S, and the seed metal layer S may have a multilayer structure including a first layer and a second layer disposed on the first layer. The first layer may include titanium (Ti), tantalum (Ta), nickel (Ni), chromium (Cr), and/or molybdenum (Mo), and may preferably include titanium (Ti) for ease of dry etching, but the present disclosure is not limited thereto. The second layer may include titanium (Ti), tantalum (Ta), nickel (Ni), chromium (Cr), copper (Cu), and/or molybdenum (Mo), and may preferably include copper (Cu) for ease of plating, but the present disclosure is not limited thereto. The second metal portion may include a plated metal layer M, and the plated metal layer M may include a third layer. The third layer may include copper (Cu), aluminum (Al), nickel (Ni), tungsten (W), and/or molybdenum (Mo), and may preferably include copper (Cu) for ease of plating, but the present disclosure is not limited thereto. The plurality of wiring layers 121, 122, 123, and 124 and the outermost wiring layer 125 may respectively perform various functions according to a design thereof. For example, the plurality of wiring layers 121, 122, 123, and 124 and the outermost wiring layer 125 may respectively include a signal transmission pattern, a power transmission pattern, and a ground transmission pattern. The above-described patterns may have various pattern forms such as a line, a trace, a plane, a pad, and the like. The pad may include a land. That is, the wirings W1, W2, W3, and W4 and pads P1, P2, P3, P4, and P5 of each of the plurality of wiring layers 121, 122, 123, and 124 and the outermost wiring layer 125 may have the above-described various pattern forms, and the number of patterns is not limited. The number of layers of the plurality of wiring layers 121, 122, 123, and 124 is not limited.

The plurality of insulating films 131, 132, 133, and 134 may include an inorganic insulating material. The inorganic insulating material may include a nitride and/or an oxide. For example, the plurality of insulating films 131, 132, 133, and 134 may respectively include a silicon nitride-based nitride, an aluminum nitride-based nitride, a boron nitride-based nitride, an aluminum oxide-based oxide, and/or a silicon oxide-based oxide, but the present disclosure is not limited thereto. The plurality of insulating films 131, 132, 133, and 134 may include another inorganic insulating material capable of preventing moisture permeation in a high-temperature and high-humidity environment and capable of being formed as a thin film. The plurality of insulating films 131, 132, 133, and 134 may include substantially the same insulating material, but the present disclosure is not limited thereto. The plurality of insulating films 131, 132, 133, and 134 may include different insulating materials, as necessary. The number of layers of the plurality of insulating films 131, 132, 133, and 134 is not limited.

The plurality of via layers 141, 142, and 143 and the outermost via layer 144 may respectively include a metal. For example, the plurality of via layers 141, 142, and 143 and the outermost via layer 144 may respectively include a third metal portion and a fourth metal portion disposed on the third metal portion, the fourth metal portion filling a via hole. The third metal portion may include the above-described seed metal layer S, and the seed metal layer S may have a multilayer structure including a first layer and a second layer disposed on the first layer. The first layer may include titanium (Ti), tantalum (Ta), nickel (Ni), chromium (Cr), and/or molybdenum (Mo), and may preferably include titanium (Ti) for ease of dry etching, but the present disclosure is not limited thereto. The second layer may include titanium (Ti), tantalum (Ta), nickel (Ni), chromium (Cr), copper (Cu), and/or molybdenum (Mo), and may preferably include copper (Cu) for ease of plating, but the present disclosure is not limited thereto. The fourth metal portion may include the above-described plated metal layer M, and the plated metal layer M may include a third layer. The third layer may include copper (Cu), aluminum (Al), nickel (Ni), tungsten (W), and/or molybdenum (Mo), and may preferably include copper (Cu) for ease of plating, but the present disclosure is not limited thereto. Connection vias V1, V2, V3, and V4 of the plurality of via layers 141, 142, and 143 and the outermost via layer 144 may include a signal transmission via, a power transmission via, and/or a ground transmission via. The connection vias V1, V2, V3, and V4 of the plurality of via layers 141, 142, and 143 and the outermost via layer 144 may have a tapered shape in the same direction. For example, in cross-section, the connection vias V1, V2, V3, and V4 may have a tapered shape in which a width of an upper portion is greater than a width of a lower portion. The number of the connection vias V1, V2, V3, and V4 of the plurality of via layers 141, 142, and 143 and the outermost via layer 144 is not limited. The number of layers of the plurality of via layers 141, 142, and 143 is not limited.

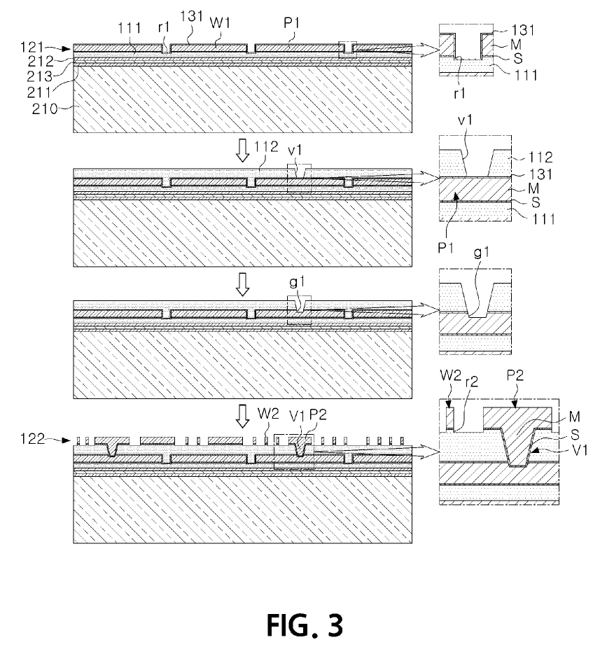

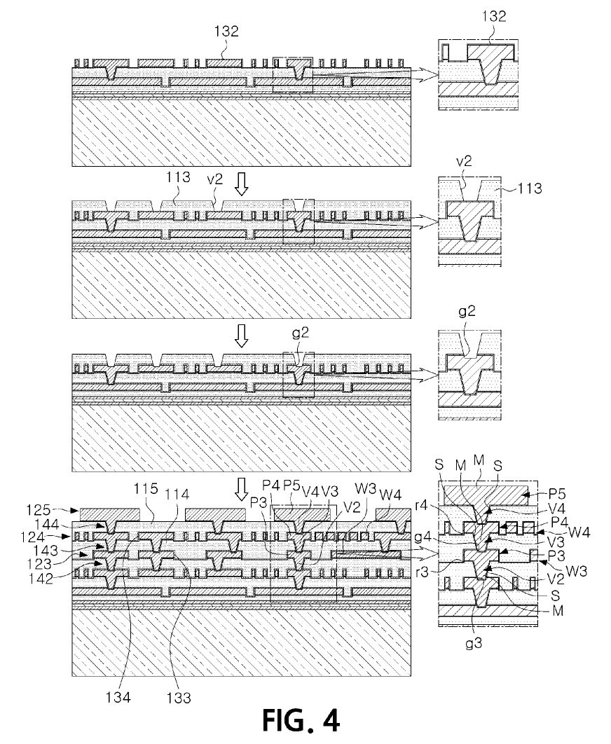

FIGS. 3 and 4 are schematic process cross-sectional views of a manufacturing example of the printed circuit board of FIG. 2.

Referring to the drawings, first, a first insulating layer 111 may be formed on a carrier 210. In addition, a first wiring layer 121 including a first wiring W1 and a first pad P1 may be formed on the first insulating layer 111. In addition, a first insulating film 131 covering the first insulating layer 111 and the first wiring layer 121 may be formed. For example, the first insulating layer 111 may be formed on the carrier 210 by coating or laminating a photosensitive organic insulating material. In addition, a seed metal layer S may be formed on the first insulating layer 111 through a deposition process, a plated metal layer M may be formed on the seed metal layer S through a plating process using a dry film or the like, the dry film may be removed, and the seed metal layer S in a region in which the dry film has been removed may be sequentially removed through wet etching and dry etching to form the first wiring layer 121 including the first wiring W1 and the first pad P1. During the dry etching process, a first recess portion r1 may be formed in the first insulating layer 111. In addition, a first insulating film 131, substantially conformally covering the first wiring layer 121 and the first recess portion r1, may be formed through a deposition process of an inorganic insulating material or the like. The carrier 210 may be formed of various materials, and may be, for example, a glass carrier, a silicon carrier, a polymer carrier, or the like. In addition, a plurality of metal films 211 and 212 and a release layer 213, disposed between the plurality of metal films 211 and 212, may be disposed on a surface of the carrier 210, but the present disclosure is not limited thereto.

Subsequently, a second insulating layer 112, covering the first insulating film 131, may be formed on the first insulating layer 111. In addition, a first via hole v1 may be formed in the second insulating layer 112. For example, the second insulating layer 112 may be formed on the first insulating layer 111 by coating or laminating an organic insulating material. In addition, a first via hole v1, penetrating the second insulating layer 112, may be formed in the first pad P1 of the first wiring layer 121 through exposure and development processes or the like.

Subsequently, the first insulating film 131 on the first pad P1, exposed through the first via hole v1, may be removed. For example, the first insulating film 131 on the first pad P1, exposed through the first via hole v1, and other metal oxides may be removed through dry etching or the like. During the dry etching process, a first groove portion g1, penetrating a portion of an upper side of the first pad P1, may be formed in the first pad P1.

Subsequently, a second wiring layer 122 including a second wiring W2 and a second pad P2 and a first via layer 141 including a first connection via V1 may be formed on the second insulating layer 112. For example, a seed metal layer S may be formed on the second insulating layer 112, the first via hole v1 and the first pad P1 exposed through the first via hole v1 through a deposition process, a plated metal layer M may be formed on the seed metal layer S through a plating process using a dry film or the like, the dry film may be removed, and the seed metal layer S in a region in which the dry film has been removed may be sequentially removed through wet etching and dry etching, thereby forming the second wiring layer 122 including the second wiring W2 and the second pad P2 and the first via layer 141 including the first connection via V1. During the dry etching process, a second recess portion r2 may be formed in the second insulating layer 112. The first groove portion g1 of the first pad P1 may be filled by the first connection via V1.

Subsequently, a second insulating film 132, covering the second insulating layer 112 and the second wiring layer 122, may be formed. For example, the second insulating film 132, substantially conformally covering the second wiring layer 122 and the second recess portion r2, may be formed through a deposition process of an inorganic insulating material or the like.

Subsequently, a third insulating layer 113, covering the second insulating film 132, may be formed on the second insulating layer 112. In addition, a second via hole v2 may be formed in the third insulating layer 113. For example, the third insulating layer 113 may be formed on the second insulating layer 112 by coating or laminating an organic insulating material. In addition, a second via hole v2, penetrating the third insulating layer 113, may be formed in the second pad P2 of the second wiring layer 122 through exposure and development processes or the like.

Subsequently, the second insulating film 132 on the second pad P2, exposed through the second via hole v2, may be removed. For example, the second insulating film 132 on the second pad P2 exposed through the second via hole v2 and other metal oxides may be removed through dry etching or the like. During the dry etching process, a second groove portion g2, penetrating a portion of an upper side of the second pad P2, may be formed in the second pad P2.

Subsequently, a third wiring layer 123 including a third wiring W3 and a third pad P3 and a second via layer 142 including a second connection via V2 may be formed in the third insulating layer 113. In addition, a third recess portion r3 may be formed in the third insulating layer 113. Detailed descriptions thereof may be substantially the same as descriptions of forming the second wiring layer 122 including the second wiring W2 and the second pad P2 and the first via layer 141 including the first connection via V1 in the second insulating layer 112.

Subsequently, the above-described build-up process may be substantially repeatedly performed to further form necessary build-up layers. For example, a fourth insulating layer 114, a fourth wiring layer 124 including a fourth wiring W4 and a fourth pad P4, a third via hole v3, a third via layer 143 including a third connection via V3, a third groove portion g3, a fourth insulating film 114, and a fourth recess portion r4 may be further formed. Thereafter, in a similar process, a fifth insulating layer 115, an outermost wiring layer 125 including an external connection pad P5, a fourth via hole v4, an outermost via layer 144 including a fourth connection via V4, and a fourth groove portion g4 may be further formed.

Subsequently, the carrier 210 may be removed. For example, the plurality of metal films 211 and 212 on the surface of the carrier 210 may be separated from each other using the release layer 213, and the metal film 212, remaining on the board, may be removed through etching, but the present disclosure is not limited thereto. Through a series of processes, the printed circuit board 100A according to an example may be manufactured. Other descriptions may be substantially the same as those of the printed circuit board 100A according to an example.

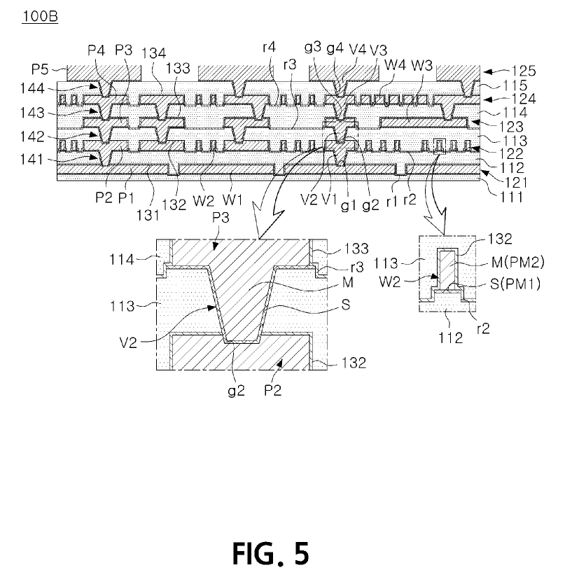

FIG. 5 is a schematic cross-sectional view of another example of a printed circuit board.

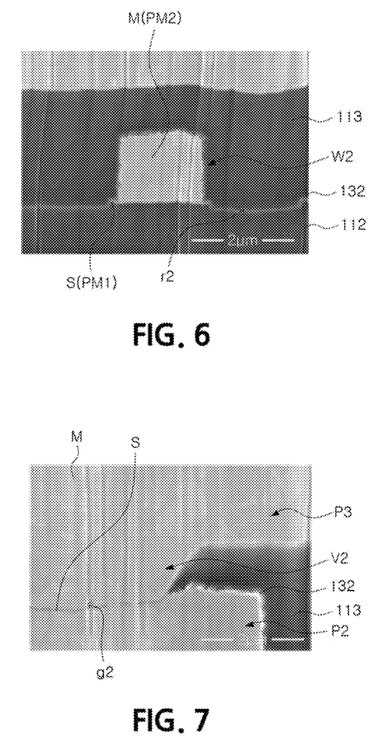

FIG. 6 is a schematic cross-sectional image of an implementation example of region “A” of the printed circuit board of FIG. 5.

FIG. 7 is a schematic cross-sectional image of an implementation example of region “B” of the printed circuit board of FIG. 5.

Referring to the drawings, as compared to the printed circuit board 100A according to an example, in a printed circuit board 100B according to another example, a region of a side surface of each of a plurality of wiring layers 121, 122, 123, and 124 in which a seed metal layer S is disposed may further protrude relatively outwardly. For example, a side surface of each of wirings W1, W2, W3, and W4 and/or pads P1, P2, P3, and P4 of the plurality of wiring layers 121, 122, 123, and 124 may have a step region. For example, the second wiring layer 122 may include a plurality of second wirings W2 disposed on a second insulating layer 112, and each of the plurality of second wirings W2 may include a first metal portion PM1 and a second metal portion PM2 disposed on the first metal portion PM1, the second metal portion PM2 thicker than the first metal portion PM1. In this case, the first metal portion PM1 may have a width greater than that of the second metal portion PM2 in cross-section. The second insulating layer 112 may have a second recess portion r2 between first metal portions of at least two adjacent wirings W2, among the plurality of second wirings W2. Accordingly, upper surfaces of regions of the second insulating layer 112 in which the plurality of second wirings W2 are disposed and not disposed may have a step portion corresponding to the second recess portion r2. The second insulating film 132 may cover the plurality of second wirings W2 and the second recess portion r2 conforming to shapes of the plurality of second wirings W2 and the second recess portion r2.

The first metal portion PM1 may include a seed metal layer S including a first layer including titanium (Ti) and a second layer disposed on the first layer, the second layer including copper (Cu), and the second metal portion PM2 may include a plated metal layer M including a third layer including copper (Cu), the third layer thicker than each of the first and second layers. In this case, when the second layer of the seed metal layer S is removed through wet etching, the second layer may partially remain on an end of a lower portion of each of the plurality of second wirings W2. Accordingly, when the first layer is subsequently removed through dry etching, the first layer may also partially remain due to the partially remaining second layer. As a result, a side surface of each of the plurality of second wirings W2 on the second insulating layer 112 may have a step portion. In this case, the seed metal layer S, specifically the first layer that may include titanium, may remain on an end of a lower portion of each of the plurality of second wirings W2. Accordingly, in a high-temperature and high-humidity environment, a migration path of a fine wiring due to moisture may be extended, which may delay moisture permeation into the wiring. As a result, reliability may be further improved.

Other descriptions may be substantially the same as those of the printed circuit board 100A according to an example. In addition, in the manufacturing example of the printed circuit board 100A according to an example, when a side surface of each of the wirings W1, W2, W3, and W4 and/or pads P1, P2, P3, and P4 of the plurality of wiring layers 121, 122, 123, and 124 is formed as a step region, the printed circuit board 100B according to another example may be manufactured.

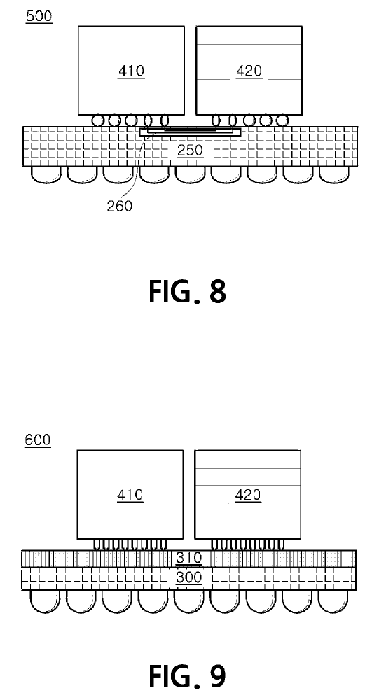

FIG. 8 is a schematic cross-sectional view of an example of a semiconductor package.

Referring to the drawings, a semiconductor package 500 according to an example may include a package substrate 250 and first and second semiconductor chips 410 and 420 mounted on the package substrate 250. A bridge substrate 260 including a fine wiring interconnecting the first and second semiconductor chips 410 and 420 may be embedded in the package substrate 250. The bridge substrate 260 may include, as an internal structure, at least one of the printed circuit boards 100A and 100B described above. The package substrate 250 may be a multilayer printed circuit board according to the related art, and a specific structure thereof is not limited. As necessary, at least one of the printed circuit boards 100A and 100B described above may be included as an internal structure of the package substrate 250. Each of the first and second semiconductor chips 410 and 420 may be a memory chip, an application processor chip, and/or a logic chip. The first and second semiconductor chips 410 and 420 may be the same type of chip or different types of chips. Other descriptions may be substantially the same as those described above, and repeated descriptions thereof will be omitted.

FIG. 9 is a schematic cross-sectional view of another example of a semiconductor package.

Referring to the drawings, a semiconductor package 600 according to another example may include a package substrate 300 and first and second semiconductor chips 410 and 420 mounted on the package substrate 300. A fine wiring layer 310 including a fine wiring interconnecting the first and second semiconductor chips 410 and 420 may be disposed on an outermost side of the package substrate 300. The fine wiring layer 310 may include at least one of the printed circuit boards 100A and 100B described above. The package substrate 300 may be a multilayer printed circuit board according to the related art, and a specific structure thereof is not limited. As necessary, at least one of the printed circuit boards 100A and 100B described above may be included as an internal structure of the package substrate 300. Each of the first and second semiconductor chips 410 and 420 may be a memory chip, an application processor chip, and/or a logic chip. The first and second semiconductor chips 410 and 420 may be the same type of chip or different types of chips. Other descriptions may be substantially the same as those described above, and repeated descriptions are omitted.

As used herein, the terms “cover,” “to cover,” and “covering” may include not only entirely covering but also at least partially covering, and may include not only directly covering but also indirectly covering. In addition, the terms “fill,” “to fill,” and “filling” may include not only entirely filling but also at least partially filling, and may also include approximately filling. For example, the terms may include a case in which some voids, pores or the like are present. In addition, the terms “surround,” “to surround,” and “surrounding” may include not only entirely surrounding but also partially surrounding, and may also include approximately surrounding. In addition, the terms “exposing” may include not only entirely exposing a structure but also exposing at least a portion of the structure, and the term “exposure” may mean exposing a component from another component in which the component is buried. For example, an opening, exposing a pad, may be exposing the pad from an outermost insulating layer, and a surface treatment layer or the like may be further disposed on the exposed pad.

As used herein, a process error or a positional deviation occurring in a manufacturing process, an error in measurement, and the like may be included. For example, “being disposed on substantially the same level” may include not only “being disposed in completely the same position” but also “being disposed in approximately the same position.” In addition, “having a substantially specific shape” may include not only “having a completely specific shape” but also “having an approximately specific shape.” For example, such a determination may be based on an overall shape. In addition, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a downward direction based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also “indirectly connected” by means of an adhesive layer or the like. The term “electrically connected” may include both a case in which components are “physically connected” and a case in which components are “not physically connected.” In addition, the terms “first,” “second,” and the like may be used to distinguish a component from another component, and may not imply any particular order and/or importance, or others in relation to the components. In some cases, a first component may be referred to as a second component, and similarly, a second component may be referred to as a first component without departing from the scope of the example embodiments.

As used herein, thickness, width, length, depth, line width, spacing, pitch, distance, and surface roughness may be measured using a scanning microscope or an optical microscope based on a cross-section obtained by polishing or cutting a printed circuit board. The cross-section may be a vertical cross-section or a horizontal cross-section, and each value may be measured based on a required cross-section. When values measured for the printed circuit board are not consistent, a value of the printed circuit board may be determined as an average value of values measured at arbitrary five points.

As used herein, the term “an example” does not mean the same example embodiment, and is provided to emphasize different unique features. However, the examples presented above do not preclude implementation in combination with features of other examples. For example, a specific feature is described in one example but not in another, it may still be understood as being applicable to the other example, unless there is an explicit contradiction or inconsistency with what is described in that other example.

The terms used herein describe particular examples only, and the present disclosure is not limited thereby. As used herein, singular forms “a,” “an,” and “the” are intended to include the plural forms as well, unless the context clearly indicates otherwise.

What is claimed is:

1. A printed circuit board comprising:
a first insulating layer having a first region and a second region;
a first wiring layer disposed on the first insulating layer; and
a first insulating film disposed on the first insulating layer, the first insulating film covering at least a portion of each of an upper surface and a side surface of the first wiring layer conforming to a shape of the first wiring layer,
wherein the first insulating layer has a first recess portion around the first wiring layer, and
wherein a depth of the first recess portion is greater than 0 μm and less than 1.0 μm.

2. The printed circuit board of claim 1, wherein the first wiring layer is disposed solely on the first region of the first insulating layer, and
wherein an upper surface of the first region of the first insulating layer and an upper surface of the second region of the first insulating layer have a step portion corresponding to the first recess portion.

3. The printed circuit board of claim 1, wherein
the first insulating film further covers at least a portion of each of a lower surface and a side surface of the first recess portion conforming to a shape of the first recess portion, and
a thickness of the first insulating film is less than the depth of the first recess portion.

4. The printed circuit board of claim 1, further comprising:
a second insulating layer disposed on the first insulating layer and having a third region and a fourth region, the second insulating layer covering the first insulating film;
a second wiring layer disposed on the second insulating layer;
a second insulating film disposed on the second insulating layer, the second insulating film covering at least a portion of each of an upper surface and a side surface of the second wiring layer conforming to a shape of the second wiring layer; and
a via layer disposed between the first wiring layer and the second wiring layer, the via layer penetrating the first insulating layer,
wherein the second insulating layer has a second recess portion around the second wiring layer.

5. The printed circuit board of claim 4, wherein the second wiring layer is disposed solely on the third region of the second insulating layer, and
wherein an upper surface of the third region of the second insulating layer and an upper surface of the fourth region of the second insulating layer have a step portion corresponding to the second recess portion.

6. The printed circuit board of claim 4, wherein
the second insulating film further covers at least a portion of each of a lower surface and a side surface of the second recess portion conforming to a shape of the second recess portion, and
a thickness of the second insulating film is less than a depth of the second recess portion.

7. The printed circuit board of claim 4, wherein
the first insulating layer and the second insulating layer respectively include a photosensitive organic insulating material, and
the first insulating film and the second insulating film respectively include an inorganic insulating material.

8. The printed circuit board of claim 7, wherein:
the photosensitive organic insulating material includes one or more of a polyimide-based resin, a phenol-based resin, and a polybenzoxazole-based resin, and
the inorganic insulating material includes one or more of a silicon nitride-based nitride, an aluminum nitride-based nitride, a boron nitride-based nitride, an aluminum oxide-based oxide, and a silicon oxide-based oxide.

9. The printed circuit board of claim 4, wherein:
the first wiring layer, the second wiring layer, and the via layer respectively include a seed metal layer, and
the seed metal layer includes a first layer including a titanium and a second layer disposed on the first layer, the second layer including a copper.

10. The printed circuit board of claim 9, wherein a region of a side surface of each of the first wiring layer and the second wiring layer on which the seed metal layer is disposed further protrudes outwardly.

11. The printed circuit board of claim 4, wherein:
the first wiring layer includes a plurality of first wirings,
the second wiring layer includes one or more second wirings, and
the plurality of first wirings is finer than the one or more second wirings.

12. The printed circuit board of claim 4, wherein:
the first wiring layer and the second wiring layer respectively include a first pad and a second pad,
the via layer includes a connection via connecting the first pad and the second pad to each other,
a region of the first pad, the region connected to the connection via, has a groove portion, and
the connection via fills the groove portion.

13. The printed circuit board of claim 12, the first insulating film is in contact with a side surface of the connection via.

14. The printed circuit board of claim 4, further comprising:
a plurality of insulating layers;
a plurality of wiring layers respectively disposed in the plurality of insulating layers;
a plurality of insulating films respectively disposed between the plurality of insulating layers, the plurality of insulating films respectively covering at least portions of the plurality of wiring layers conforming to shapes of the plurality of wiring layers; and
a plurality of via layers respectively disposed in the plurality of insulating layers, the plurality of via layers respectively connecting the plurality of wiring layers to each other,
wherein the plurality of insulating layers includes the first insulating layer and the second insulating layer,
wherein the plurality of wiring layers includes the first wiring layer and the second wiring layer,
wherein the plurality of insulating films includes the first insulating film and the second insulating film, and
wherein the plurality of via layers includes the via layer.

15. The printed circuit board of claim 14, further comprising:
an outermost wiring layer disposed on an uppermost insulating layer, among the plurality of insulating layers; and
an outermost via layer disposed in the uppermost insulating layer, the outermost via layer connecting an uppermost wiring layer, among the plurality of wiring layers, and the outermost wiring layer to each other,
wherein the outermost wiring layer includes a plurality of external connection pads.

16. A printed circuit board comprising:
a first insulating layer having a first region and a second region;
a plurality of wirings disposed on the first insulating layer; and
an insulating film disposed on the first insulating layer, the insulating film covering each of the plurality of wirings conforming to a shape of each of the plurality of wirings,
wherein each of the plurality of wirings includes a first metal portion and a second metal portion disposed on the first metal portion, the second metal portion being thicker than the first metal portion,
wherein the first metal portion has a width greater than a width of the second metal portion in cross-section, and
wherein the first insulating layer has a recess portion disposed between the first metal portion of each of at least two adjacent wirings, among the plurality of wirings.

17. The printed circuit board of claim 16, wherein:
the first metal portion includes a first layer including a titanium and a second layer disposed on the first layer, the second layer including a copper,
the second metal portion includes a third layer including a copper, and
the third layer is thicker than each of the first and second layers.

18. The printed circuit board of claim 16, wherein the plurality of wiring layer is disposed solely on the first region of the first insulating layer, and
wherein an upper surface of the first region of the first insulating layer and an upper surface of the second region of the first insulating layer have a step portion corresponding to the recess portion.

19. The printed circuit board of claim 16, wherein:
the insulating film covers at least a portion of the recess portion conforming to a shape of the recess portion, and
a thickness of the insulating film is less than a depth of the recess portion.

20. The printed circuit board of claim 16, further comprising:
a second insulating layer disposed on the first insulating layer, the second insulating layer covering at least a portion of the insulating film,
wherein the first insulating layer and the second insulating layer respectively include a photosensitive organic insulating material including one or more of a polyimide-based resin, a phenol-based resin, and a polybenzoxazole-based resin, and
wherein the insulating film includes an inorganic insulating material including one or more of a silicon nitride-based nitride, an aluminum nitride-based nitride, a boron nitride-based nitride, an aluminum oxide-based oxide, and a silicon oxide-based oxide.
